(19) United States
(12) Patent Application Publication
(10) Pub. No.: US 2024/0392469 A1
(43) Pub. Date: Nov. 28, 2024

(54) METHOD FOR PREPARING SILICON SINGLE CRYSTAL ROD AND SINGLE CRYSTAL FURNACE

(71) Applicants: JINKO SOLAR CO., LTD., Jiangxi (CN); ZHEJIANG JINKO SOLAR CO., LTD., Haining (CN)

(72) Inventors: Xuejian WAN, Jiangxi (CN); Weize SHANG, Jiangxi (CN); Xiaolong BAI, Jiangxi (CN); Ziyang OU, Jiangxi (CN)

(21) Appl. No.: 18/518,918

(22) Filed: Nov. 24, 2023

(30) Foreign Application Priority Data
May 23, 2023 (CN) 202310587021.7
Jun. 29, 2023 (CN) 202310790173.7

(51) Int. Cl. C30B 15/22; C30B 29/06

(52) U.S. Cl. CPC C30B 15/22; C30B 29/06

(57) ABSTRACT

A method for preparing a silicon single crystal rod is provided. The method includes a crystal pulling process including a melt contacting operation, a seeding operation, a shoulder releasing operation, a shoulder rotating operation, a diameter equalizing operation, and a closing operation in sequence. Each operation of the crystal pulling process has a furnace pressure less than or equal to 500 Pa and a pumping rate greater than or equal to 1000 m³/h.

### CROSS-REFERENCE TO RELATED APPLICATION

The present disclosure claims the benefit of priorities under the Paris Convention to Chinese Patent Application 202310587021.7 filed on May 23, 2023 and Chinese Patent Application No. 202310790173.7 filed on Jun. 29, 2023, each of which is incorporated herein by reference in its entirety.

### TECHNICAL FIELD

Embodiments of the present disclosure relate in general to crystal growth, and more specifically to a method for preparing a silicon single crystal rod and a single crystal furnace.

### BACKGROUND

Monocrystalline silicon is one of the necessary materials for production and manufacture of chips and solar cells. At present, in all mounted solar cells, more than 90% are crystalline silicon solar cells. Therefore, the production of monocrystalline silicon at the front end of an industrial chain has a very important role in the entire solar cell industry.

A Czochralski method is a crystal growth method established by Czochralski, referred to as CZ method for short. In a conventional process of growing a silicon single crystal rod through the CZ method, equal-diameter growth is very important. For the equal-diameter growth process, a set of target pulling speeds need to be manually set in related technologies, i.e., a slope value of a growth length of the silicon single crystal rod needs to be set manually.

A main impurity in the silicon single crystal rod is oxygen, and normally, the oxygen is introduced in the growth process of the silicon single crystal rod. Due to the influence of thermal history, the head of the silicon single crystal rod remains at a high temperature for a long time and is slow to be cooled during the cooling process of the silicon single crystal rod. As a result, the oxygen existing in gaps is converged at 450° C. to generate an electrically active SiO₄²⁻, providing electrons to be an oxygen donor. However, the oxygen donor easily induces layer errors and defects, causing silicon wafers to warp so as to introduce a large number of secondary defects, thereby affecting mechanical properties of single crystal cells, having a destructive effect on electrical properties of silicon materials and devices, and reducing conversion efficiency of single crystal cells.

### SUMMARY

Some embodiments of the present disclosure provide a method for preparing a silicon single crystal rod, which is at least conducive to reducing an oxygen content in the silicon single crystal rod.

Some embodiments of the present disclosure provide a method for preparing a silicon single crystal rod, including: a crystal pulling process including a melt contacting operation, a seeding operation, a shoulder releasing operation, a shoulder rotating operation, a diameter equalizing operation, and a closing operation in sequence, where each operation of the crystal pulling process has a furnace pressure less than or equal to 500 Pa and a pumping rate greater than or equal to 1000 m³/h.

In some embodiments, a furnace pressure of each operation gradually decreases as the crystal pulling process advances.

In some embodiments, a furnace pressure of the melt contacting operation is in a range of 450 Pa to 500 Pa, a furnace pressure of the seeding operation is in a range of 400 Pa to 450 Pa, a furnace pressure of the shoulder releasing operation is in a range of 400 Pa to 450 Pa, a furnace pressure of the shoulder rotating operation is in a range of 300 Pa to 400 Pa, a furnace pressure of the diameter equalizing operation is in a range of 300 Pa to 400 Pa, and a furnace pressure of the closing operation is in a range of 300 Pa to 400 Pa.

In some embodiments, an inert gas flow rate of each operation gradually decreases as the crystal pulling process advances.

In some embodiments, an inert gas flow rate of the melt contacting operation is in a range of 120 slpm to 150 slpm, an inert gas flow rate of the seeding operation is in a range of 100 slpm to 120 slpm, an inert gas flow of the shoulder releasing operation is in a range of 100 slpm to 120 slpm, an inert gas flow of the shoulder rotating operation is in a range of 100 slpm to 120 slpm, an inert gas flow rate of the diameter equalizing operation is in a range of 100 slpm to 120 slpm, and an inert gas flow rate of the closing operation is in a range of 100 slpm to 120 slpm.

In some embodiments, a crystal rotation rate and a pot rotation rate of each operation gradually increase as the crystal pulling process advances.

In some embodiments, a crystal rotation rate of the melt contacting operation is in a range of 6 rpm to 10 rpm, and a pot rotation rate of the melt contacting operation is in a range of 2 rpm to 6 rpm; a crystal rotation rate of the seeding operation is in a range of 6 rpm to 10 rpm, and a pot rotation rate of the seeding operation is in a range of 2 rpm to 6 rpm; a crystal rotation rate of the shoulder releasing operation is in a range of 6 rpm to 10 rpm, and a pot rotation rate of the shoulder releasing operation is in a range of 2 rpm to 6 rpm; a crystal rotation rate of the shoulder rotating operation is in a range of 8 rpm to 10 rpm, and a pot rotation rate of the shoulder rotating operation is in a range of 4 rpm to 7 rpm; a crystal rotation rate of the diameter equalizing operation is in a range of 8 rpm to 10 rpm, and a pot rotation rate of the diameter equalizing operation is in a range of 4 rpm to 7 rpm; and a crystal rotation rate of the closing operation is in a range of 8 rpm to 10 rpm, and a pot rotation rate of the closing operation is in a range of 4 rpm to 7 rpm.

In some embodiments, a pumping rate of the melt contacting operation is greater than pumping rates of other operations in the crystal pulling process.

In some embodiments, a pumping rate of each operation following the melt contacting operation gradually increases as the crystal pulling process advances.

In some embodiments, the pumping rate of the melt contacting operation is in a range of 2100 m³/h to 2300 m³/h, a pumping rate of the seeding operation is in a range of 1600 m³/h to 1800 m³/h, a pumping rate of the shoulder releasing operation is in a range of 1600 m³/h to 1800 m³/h, a pumping rate of the shoulder rotating operation is in a range of 1600 m³/h to 1800 m³/h, a pumping rate of the diameter equalizing operation is in a range of 1800 m³/h to 2100 m³/h, and a pumping rate of the closing operation is in a range of 1800 m³/h to 2100 m³/h.

In some embodiments, the shoulder releasing operation includes a flat shoulder releasing process.

### BRIEF DESCRIPTION OF THE DRAWINGS

One or more embodiments are exemplarily described with figures in the accompanying drawings corresponding thereto, which are not intended to limit these embodiments. Unless otherwise stated, the figures in the accompanying drawings do not constitute scale limitations. In order to more clearly illustrate the technical solutions in the embodiments of the present disclosure or conventional technologies, the accompanying drawings that need to be used in the embodiments are briefly described below, and it is apparent that the drawings in the following description are merely some embodiments of the present disclosure. For a person of ordinary skill in the art, other drawings may also be obtained according to these drawings.

FIG. 1 is a flowchart of a method for preparing a silicon single crystal rod according to an embodiment of the present disclosure.

FIG. 2 is a schematic structural diagram of a single crystal furnace.

FIG. 3 is a schematic structural diagram of a single crystal furnace according to an embodiment of the present disclosure.

FIG. 4 is another schematic structural diagram of a single crystal furnace according to an embodiment of the present disclosure.

FIG. 5 is a schematic structural diagram of some components in the single crystal furnace provided in FIG. 4.

FIG. 6 is yet another schematic structural diagram of a single crystal furnace according to an embodiment of the present disclosure.

FIG. 7 is still another schematic structural diagram of a single crystal furnace according to an embodiment of the present disclosure.

FIG. 8 is a flowchart of each operation in a method for preparing a silicon single crystal rod according to an embodiment of the present disclosure.

FIG. 9 and FIG. 10 are schematic structural diagrams corresponding to some operations of a method for preparing a silicon single crystal rod according to an embodiment of the present disclosure.

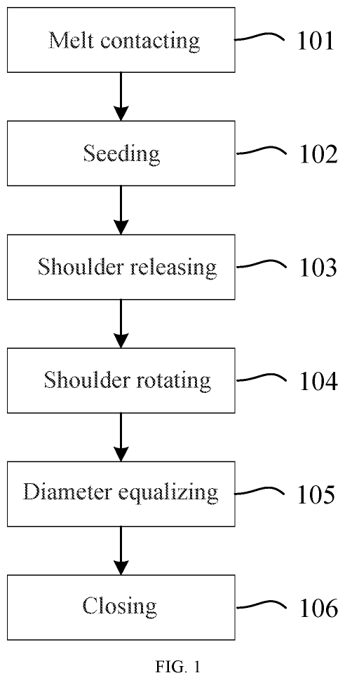

### DETAILED DESCRIPTION OF THE EMBODIMENTS

Embodiments of the present disclosure provide a method for preparing a silicon single crystal rod, which is at least conducive to reducing the oxygen content in the silicon single crystal rod.

A crystal pulling process (i.e., silicon single crystal rod preparing process) includes a melt contacting operation 101, a seeding operation 102, a shoulder releasing operation 103, a shoulder rotating operation 104, a diameter equalizing operation 105, and a closing operation 106, etc.

In the melt contacting operation 101, polysilicon materials and dopants (such as boron or phosphorus, etc.) are put into a quartz crucible, a single crystal furnace is closed and vacuumed, and a heater is turned on to melt the polysilicon materials after a leakage test is passed. When all the polysilicon materials are melted, a heating power is adjusted to control the temperature of the melt, and then the inert gas flow rate, furnace pressure, crucible position, crystal rotation rate, and crucible rotation rate are adjusted according to process requirements. After all the polysilicon materials are melted, the melt must be stabilized for a certain period of time to achieve stability of temperature and flow of the melt. After the melt is stabilized, a seed crystal is lowered to a distance of 3 mm to 5 mm from a liquid surface of the melt, so that the seed crystal is preheated to reduce the temperature difference between the seed crystal and the molten silicon, thus reducing thermal stress generated in the seed crystal when the seed crystal contacts with the molten silicon. After preheating, the seed crystal is dropped to the surface of the melt to allow the seed crystal to make full contact with the melt, this process known as melt contacting. In the melt contacting process, attention should be paid to observe the occurring phenomena to determine whether the temperature of the surface of the melt is appropriate. In an appropriate temperature, a halo (often referred to as “aperture”) caused by a crescent surface at the solid-liquid-gas three-phase intersection is gradually shown at an interface after the melt contacting, and the halo shows from a part of the aperture to become a complete circular aperture. If the temperature is too high, the seed crystal may be melted off. If the temperature is too low, the halo caused by the crescent surface may not appear, and even polycrystals may grow.

The next operation is the seeding operation 102, when the seed crystal is inserted into the melt, dislocations are generated due to thermal stress and surface tension caused by the temperature difference between the seed crystal and the melt. The seeding operation 102 after the melt contacting operation 101 makes the dislocations disappear and establishes a dislocation-free growth state. The seeding operation 102 is usually performed at a high pulling speed to reduce a diameter of the crystal to approximately 3 mm. Under these conditions, the thermal stress during cooling is very small, no new dislocations are created, and the high pulling speed may create supersaturation point defects.

The next operation is the shoulder releasing operation 103. The diameter of the crystal must be enlarged to a target diameter after the seeding operation 102 is completed, and the pulling speed is reduced to release the shoulder when a thin neck grows to a sufficient length and reaches a certain pulling speed. The shoulder releasing operation 103 includes a flat shoulder releasing process, i.e., an angle between the shoulders is close to 180°, which reduces loss of materials in the head of the crystal.

The next operation is the shoulder rotating operation 104, and shoulder rotating is required when crystal growth is turned from the shoulder releasing operation 103 to the diameter equalizing operation 105. When the diameter of the crystal is close to the preset target diameter in shoulder releasing, the pulling rate is increased, and the crystal is gradually into equal diameter growth. In order to keep a level position of the liquid surface unchanged, crucible rise is started during or after the shoulder rotating, generally with appropriate crucible rise and make it change with crystal rise. During the shoulder releasing, the diameter of the crystal increases very quickly, almost no crescent-surface halo is present. In the process of the shoulder rotating, the crescent-surface halo gradually appears, and a width and brightness of the crescent-surface halo increase. Crystal pulling operators need to accurately determine changes in the diameter based on the width and brightness of the crescent-surface halo, and adjust the pulling speed in time, to ensure that the shoulder rotating is smooth and the diameter of the crystal is uniform and achieves the target value.

The next operation is the diameter equalizing operation 105, in which not only the diameter of the crystal should be controlled, but also the dislocation-free growth of the crystal is more important. There are always thermal stresses in the crystal, an isothermal surface cannot be kept absolutely flat during the growth process, and there is a radial temperature gradient as long as the isothermal surface is not flat. Besides, an axial temperature distribution in the crystal tends to be in the form of an exponential function, which also inevitably causes thermal stresses. When these thermal stresses exceed a critical stress of silicon, dislocations occur in the crystal. Therefore, it is required to control the radial temperature gradient and axial temperature gradient to be not too large, so that the thermal stresses do not exceed the critical stress of silicon, to meet such a condition in order to maintain the dislocation-free growth. Moreover, refractory solid particles, furnace dust (particles formed by SiO volatilized in the melt in the crucible and cooled in the furnace atmosphere), exfoliation of the crucible after peeling, and the like in polycrystals cause generation of dislocations (often referred to as bract fracture) when moving to the growth interface. This is because the particles and exfoliation act as a crystallographic nucleus for non-uniform nucleation or to be a source of dislocations. The temperature gradient in the crystal is able to be changed by adjusting a structure of the thermal field and an initial position of the crucible in the thermal field. By adjusting the inert gas flow rate, the furnace pressure, and the flow direction of the gas, volatile SiO and harmful impurity CO gas are able to be taken away and the furnace dust is prevented from falling off, which is conducive to the growth of the dislocation-free single crystal, and also has the effect of changing the temperature gradient in the crystal.

The next operation is the closing operation 106, and a role of the closing is to prevent dislocation reverse-extension. In the crystal pulling process, when the dislocation-free growth state is interrupted or the crystal pulling is completed so that the crystal is suddenly detached from the liquid surface, dislocation-free crystals that have been grown are subjected to a thermal shock, and their thermal stresses tend to exceed the critical stress of silicon. At this time, the dislocations occur and are reversely extended into a crystal whose temperature is still at the lowest temperature of plastic deformation, to form dislocation rows in star-shaped structure.

A dry pump of the single crystal furnace is at the bottom of the thermal field and a furnace pressure monitoring position is at the bottom plate of the single crystal furnace, so that the furnace pressure near the position of the dry pump is relatively low and the further away from the dry pump the higher the furnace pressure is, which is not conducive to control of oxygen impurities in the crystal pulling process.

In the method for preparing the silicon single crystal rod provided in embodiments of the present disclosure, the furnace pressure is less than or equal to 500 Pa, and a pumping rate is greater than or equal to 1000 m³/h in each operation of the crystal pulling process described above. The furnace pressure refers to the pressure inside the single crystal furnace, and the pumping rate refers to a rate at which the gas inside the single crystal furnace is pumped out to the outside of the single crystal furnace. In this way, by controlling the furnace pressure to be lower and the pumping rate to be higher, a volatilization rate of oxygen impurities is enhanced and atmosphere circulation inside the single crystal furnace is accelerated, so that pressures of various parts of the single crystal furnace are equalized to weaken imbalance of the pressures of various parts of the single crystal furnace, so as to be conducive to the crystal pulling process. In addition, the lower furnace pressure and the higher pumping rate are conducive to rapid flow of the inert gas from a guide cylinder to the top of the free liquid surface, and then through a side wall of the crucible to the bottom of the single crystal furnace to discharge. An inert gas flow velocity above the free liquid surface increases, and accordingly, the rate of the oxygen impurities being taken out is faster, so as to reduce the oxygen impurities in the silicon single crystal rod and improve the quality of the silicon single crystal rod.

In some embodiments, a furnace pressure of the melt contacting operation 101 is in a range of 450 Pa to 500 Pa, such as 450 Pa, 455 Pa, 460 Pa, 465 Pa, 470 Pa, 475 Pa, 480 Pa, 485 Pa, 490 Pa, 495 Pa, 500 Pa, etc. A furnace pressure of the seeding operation 102 is in a range of 400 Pa to 450 Pa, such as 400 Pa, 405 Pa, 410 Pa, 415 Pa, 420 Pa, 425 Pa, 430 Pa, 435 Pa, 440 Pa, 445 Pa, 450 Pa, etc. A furnace pressure of the shoulder releasing operation 103 is in a range of 400 Pa to 450 Pa, such as 400 Pa, 405 Pa, 410 Pa, 415 Pa, 420 Pa, 425 Pa, 430 Pa, 435 Pa, 440 Pa, 445 Pa, 450 Pa, etc. A furnace pressure of the shoulder rotating operation 104 is in a range of 300 Pa to 400 Pa, such as 300 Pa, 310 Pa, 320 Pa, 330 Pa, 340 Pa, 350 Pa, 360 Pa, 370 Pa, 380 Pa, 390 Pa, 400 Pa, etc. A furnace pressure of the diameter equalizing operation 105 is in a range of 300 Pa to 400 Pa, such as 300 Pa, 310 Pa, 320 Pa, 330 Pa, 340 Pa, 350 Pa, 360 Pa, 370 Pa, 380 Pa, 390 Pa, 400 Pa, etc. A furnace pressure of the closing operation 106 is in a range of 300 Pa to 400 Pa, such as 300 Pa, 310 Pa, 320 Pa, 330 Pa, 340 Pa, 350 Pa, 360 Pa, 370 Pa, 380 Pa, 390 Pa, 400 Pa, etc. A furnace pressure of the closing operation 106 is in a range of 300 Pa to 400 Pa, such as 300 Pa, 310 Pa, 320 Pa, 330 Pa, 340 Pa, 350 Pa, 360 Pa, 370 Pa, 380 Pa, 390 Pa, 400 Pa, etc.

Reference is made to the following Comparative Examples.

Comparative Example 1: In the crystal pulling process, the furnace pressure of the melt contacting operation 101 is 1300 Pa, the furnace pressure of the seeding operation 102 is 1300 Pa, the furnace pressure in the shoulder releasing operation 103 is 1300 Pa, the furnace pressure in the shoulder rotating operation 104 is 1300 Pa, the furnace pressure in the diameter equalizing operation 105 is 1300 Pa, the furnace pressure in the closing operation 106 is 1300 Pa, and other process conditions are unchanged during the crystal pulling process.

Compare Example 2: In the crystal pulling process, the furnace pressure of the melt contacting operation 101 is 500 Pa, the furnace pressure of the seeding operation 102 is 500 Pa, the furnace pressure of the shoulder releasing operation 103 is 500 Pa, the furnace pressure of the shoulder turning operation 104 is 500 Pa, the furnace pressure of the diameter equalizing operation 105 is 500 Pa, and the furnace pressure of the closing operation 106 is 500 Pa, and other process conditions are unchanged during the crystal pulling process.

Comparative Example 3: In the crystal pulling process, the furnace pressure of the melt contacting operation 101 is 500 Pa, the furnace pressure of the seeding operation 102 is 450 Pa, the furnace pressure of the shoulder releasing operation 103 is 400 Pa, the furnace pressure of the shoulder rotating operation 104 is 350 Pa, the furnace pressure of the diameter equalizing operation 105 is 320 Pa, and the furnace pressure of the closing operation 106 is 300 Pa, and other process conditions are unchanged during the crystal pulling process.

A radial oxygen variation (ROV) value (radial uniformity of oxygen content) and oxygen content of each of the silicon single crystal rods prepared in the above three Comparative Examples are tested. In each Comparative Example, 50 silicon single crystal rods are taken as test samples. Each of the silicon single crystal rods is cut at a distance of 100 mm from the head of the silicon single crystal rod, a corresponding ROV value and oxygen content are then tested, and an average value of all the tested ROV values and an average value of all the tested oxygen contents are calculated. Since the first 100 mm of the silicon single crystal rod has a large number of defects and oxygen impurities, the test at 100 mm from the head of the silicon single crystal rod is chosen to judge the quality of the silicon single crystal rod.

The test results are as follows:

| | ROV Value (%) | Oxygen Content (PPMA) |
|---|---|---|
| Comparative Example 1 | 13.2 | 12.58 |
| Comparative Example 2 | 12.1 | 11.34 |
| Comparative Example 3 | 11.4 | 10.56 |

It is found from Comparative Example 1 and Comparative Example 2 that the furnace pressure of each operation in the crystal pulling process of Comparative Example 1 is greater than 500 Pa, the furnace pressure of each operation in the crystal pulling process of Comparative Example 2 is equal to 500 Pa, and the furnace pressure of each operation in Comparative Example 2 is less than the furnace pressure of the corresponding operation in Comparative Example 1. In this way, the ROV value and the oxygen content of the silicon single crystal rod prepared by the method in Comparative Example 2 are reduced compared to those of the silicon single crystal rod prepared by the method in Comparative Example 1, respectively. That is, the radial uniformity of the oxygen content is improved, and the oxygen content is reduced, thus improving the quality of the silicon single crystal rod. It is seen that the reduction of furnace pressure in the single crystal furnace is conducive to improving the quality of the silicon single crystal rod, because the low furnace pressure accelerates the volatilization of oxygen, and at the same time effectively accelerates gas circulation, so that the oxygen content of the head of the silicon single crystal rod is reduced and the radial uniformity of the oxygen content is increased.

It is found from Comparative Example 2 and Comparative Example 3 that the furnace pressures of different operations are unchanged in the crystal pulling process of Comparative Example 2, and the furnace pressures of different operations gradually decrease as the crystal pulling process advances in the crystal pulling process of Comparative Example 3. In this way, the ROV value and the oxygen content of the silicon single crystal rod prepared by the method in Comparative Example 3 are reduced compared to those of the silicon single crystal rod prepared by the method in Comparative Example 2, respectively. That is, the radial uniformity of the oxygen content is improved, and the oxygen content is reduced, thus improving the quality of the silicon single crystal rod. It is seen that the furnace pressures of the different operations gradually decrease as the crystal pulling process advances, which is conducive to reducing the oxygen content in the silicon single crystal rod and improving the quality of the silicon single crystal rod. Because a power of the diameter equalizing rises as a depth of the silicon material decreases, corrosion of the crucible is accelerated, thus a lower furnace pressure is needed to quickly take away the oxygen impurities.

In some embodiments, a pumping rate of the melt contacting operation 101 is in a range of 2100 m³/h to 2300 m³/h, such as 2100 m³/h, 2150 m³/h, 2200 m³/h, 2250 m³/h, 2300 m³/h, etc. A pumping rate of the seeding operation 102 is in a range of 1600 m³/h to 1800 m³/h, such as 1600 m³/h, 1650 m³/h, 1700 m³/h, 1750 m³/h, 1800 m³/h, etc. A pumping rate of the shoulder releasing operation 103 is in a range of 1600 m³/h to 1800 m³/h, such as 1600 m³/h, 1650 m³/h, 1700 m³/h, 1750 m³/h, 1800 m³/h, etc. A pumping rate of the shoulder turning operation 104 is in a range of 1600 m³/h to 1800 m³/h, such as 1600 m³/h, 1650 m³/h, 1700 m³/h, 1750 m³/h, 1800 m³/h, etc. A pumping rate of the diameter equalizing operation 105 is in a range of 1800 m³/h to 2100 m³/h, such as 1800 m³/h, 1850 m³/h, 1900 m³/h, 1950 m³/h, 2000 m³/h, 2050 m³/h, 2100 m³/h, etc. A pumping rate of the closing operation 106 is in a range of 1800 m³/h to 2100 m³/h, such as 1800 m³/h, 1850 m³/h, 1900 m³/h, 1950 m³/h, 2000 m³/h, 2050 m³/h, 2100 m³/h, etc.

In some embodiments, the pumping rate is adjusted by adjusting a pumping speed of a Roots pump in the crystal pulling system.

Reference is made to the following Comparative Examples.

Comparative Example 4: In the crystal pulling process, the pumping rate of the melt contacting operation 101 is 500 m³/h, the pumping rate of the seeding operation 102 is 500 m³/h, the pumping rate of the shoulder releasing operation 103 is 500 m³/h, the pumping rate of the shoulder rotating operation 104 is 500 m³/h, the pumping rate of the diameter equalizing operation 105 is 500 m³/h, and the pumping rate of the closing operation 106 is 500 m³/h, and other process conditions are unchanged during the crystal pulling process.

Compare Example 5: In the crystal pulling process, the pumping rate of the melt contacting operation 101 is 1200 m³/h, the pumping rate of the seeding operation 102 is 1200 m³/h, the pumping rate of the shoulder releasing operation 103 is 1200 m³/h, the pumping rate of the shoulder rotating operation 104 is 1200 m³/h, the pumping rate of the diameter equalizing operation 105 is 1200 m³/h, the pumping rate of the closing operation 106 is 1200 m³/h, and other process conditions are unchanged during the crystal pulling process.

Compare Example 6: In the crystal pulling process, the pumping rate of the melt contacting operation 101 is 2300 m³/h, the pumping rate of the seeding operation 102 is 1600 m³/h, the pumping rate of the shoulder releasing operation 103 is 1700 m³/h, the pumping rate of the shoulder rotating operation 104 is 1800 m³/h, the pumping rate of the equalization operation 105 is 1900 m³/h, and the pumping rate of the closing operation 106 is 2100 mh, and other process conditions are unchanged during the crystal pulling process.

The ROV value (radial uniformity of oxygen content) and oxygen content of each of the silicon single crystal rods prepared in the above three Comparative Examples are tested. In each Comparative Example, 50 silicon single crystal rods are taken as test samples. Each of the silicon single crystal rods is cut at a distance of 100 mm from the head of the silicon single crystal rod, a corresponding ROV value and oxygen content are then tested, and an average value of all the tested ROV values and an average value of all the tested oxygen contents are calculated. Since the first 100 mm of the silicon single crystal rod has a large number of defects and oxygen impurities, the test at 100 mm from the head of the silicon single crystal rod is chosen to judge the quality of the silicon single crystal rod.

The test results are as follows:

| | ROV Value (%) | Oxygen Content (PPMA) |
|---|---|---|
| Comparative Example 4 | 13.7 | 12.66 |
| Comparative Example 5 | 12.4 | 11.43 |
| Comparative Example 6 | 11.3 | 10.24 |

It is found from Comparative Example 4 and Comparative Example 5 that the pumping rate of each operation is less than 1000 m³/h in the crystal pulling process of Comparative Example 4, the pumping rate of each operation is more than 1000 m³/h in the crystal pulling process of Comparative Example 5, and the pumping rate of each operation in Comparative Example 5 is less than the pumping rate of the corresponding operation in Comparative Example 4. In this way, the ROV value and the oxygen content of the silicon single crystal rod prepared by the method in Comparative Example 5 are reduced compared to those of the silicon single crystal rod prepared by the method in Comparative Example 4, respectively. That is, the radial uniformity of the oxygen content is improved, and the oxygen content is reduced, thus improving the quality of the silicon single crystal rod. It is seen that the increase in the pumping rate helps to improve the quality of the silicon single crystal rod. Due to the lower furnace pressure of the single crystal furnace, a corresponding pumping speed of the dry pump is larger, so the flow rate of the inert gas is able to be increased if improving the pumping rate, which is also conducive to the single crystal furnace to keep a lower furnace pressure, thereby improving the quality of the silicon single crystal rod.

It is found from Comparative Example 5 and Comparative Example 6 that the pumping rates of different operations are unchanged in the crystal pulling process of Comparative Example 5, and the pumping rate of the melt contacting operation is greater than the pumping rates of other operations in the crystal pulling process of Comparative Example 6. In this way, the ROV value and the oxygen content of the silicon single crystal rod prepared by the method in Comparative Example 6 are reduced compared to those of the silicon single crystal rod prepared by the method in Comparative Example 5, respectively. That is, the radial uniformity of the oxygen content is improved, and the oxygen content is reduced, thus improving the quality of the silicon single crystal rod. Since a higher heating power of the melt contacting operation 101 produces more oxygen impurities, which requires a greater pumping rate, the pumping rate of the melt contacting operation 101 is able to be greater than the pumping rate of the other operations.

In addition, the pumping rates of the different operations after the melt contacting operation 101 gradually decrease as the crystal pulling process advances, which is conducive to improving the quality of the silicon single crystal rod. Because the power of the diameter equalizing rises as the depth of the silicon material decreases, corrosion of the crucible is accelerated, thus a greater pumping rate is needed to quickly take away the oxygen impurities.

In some embodiments, inert gas flow rates of different operations gradually decrease as the crystal pulling process advances. It should be understood that the gas flow rate becomes small with the reduction of the furnace pressure in the case that the pumping rate remains unchanged, and an amount of gas that needs to be pumped out per unit of time reduces, such that the gas flow velocity increases and the corresponding inert gas takes away the oxygen impurities faster, which is more conducive to enhancing the quality of silicon single crystal rod.

For example, an inert gas flow rate of the melt contacting operation 101 is in a range of 120 slpm to 150 slpm, such as 120 slpm, 125 slpm, 130 slpm, 135 slpm, 140 slpm, 145 slpm, 150 slpm, etc. An inert gas flow rate of the seeding operation 102 is in a range of 100 slpm to 120 slpm, such as 100 slpm, 105 slpm, 110 slpm, 115 slpm, 120 slpm, etc. An inert gas flow rate of the shoulder releasing operation 103 is in a range of 100 slpm to 120 slpm, such as 100 slpm, 105 slpm, 110 slpm, 115 slpm, 120 slpm, etc. An inert gas flow rate of the shoulder rotating operation 104 is in a range of 100 slpm to 120 slpm, such as 100 slpm, 105 slpm, 110 slpm, 115 slpm, 120 slpm, etc. An inert gas flow rate of the diameter equalizing operation 105 is in a range of 100 slpm to 120 slpm, such as 100 slpm, 105 slpm, 110 slpm, 115 slpm, 120 slpm, etc. An inert gas flow rate of the closing operation 106 is in a range of 100 slpm to 120 slpm, such as 100 slpm, 105 slpm, 110 slpm, 115 slpm, 120 slpm, etc.

In some embodiments, crystal rotation rates and pot rotation rates of different operations are increased as the crystal pulling process advances. The increase of the crystal rotation rate is conducive to improving radial uniformity of the silicon signal crystal rod, and the increase of the crucible rotation effectively reduces a thickness of a boundary diffusion layer, which is conducive to the growth of the silicon signal crystal rod.

In some embodiments, the fusing operation 101 has a crystal rotation rate in a range of 6 rpm to 10 rpm, such as 6 rpm, 7 rpm, 8 rpm, 9 rpm, 10 rpm, etc., and a pot rotation rate in a range of 2 rpm to 6 rpm, such as 2 rpm, 3 rpm, 4 rpm, 5 rpm, 6 rpm, etc. The seeding operation 102 has a crystal rotation rate in a range of 6 rpm to 10 rpm, such as 6 rpm, 7 rpm, 8 rpm, 9 rpm, 10 rpm, etc., and a pot rotation rate in a range of 2 rpm to 6 rpm, such as 2 rpm, 3 rpm, 4 rpm, 5 rpm, 6 rpm, etc. The shoulder releasing operation 103 has a crystal rotation rate in a range of 6 rpm to 10 rpm, such as 6 rpm, 7 rpm, 8 rpm, 9 rpm, 10 rpm, etc., and a pot rotation rate in a range of 2 rpm to 6 rpm, such as 2 rpm, 3 rpm, 4 rpm, 5 rpm, 6 rpm, etc. The shoulder rotating operation 104 has a crystal rotation rate in a range of 8 rpm to 10 rpm, such as 8 rpm, 8.5 rpm, 9 rpm, 9.5 rpm, 10 rpm, etc., and a pot rotation rate in a range of 4 rpm to 7 rpm, such as 4 rpm, 5 rpm, 6 rpm, 7 rpm, etc. The diameter equalizing operation 105 has a crystal rotation rate in a range of 8 rpm to 10 rpm, such as 8 rpm, 8.5 rpm, 9 rpm, 9.5 rpm, 10 rpm, etc., and a pot rotation rate in a range of 4 rpm to 7 rpm, such as 4 rpm, 5 rpm, 6 rpm, 7 rpm, etc. The closing operation 106 has a crystal rotation rate in a range of 8 rpm to 10 rpm, such as 8 rpm, 8.5 rpm, 9 rpm, 9.5 rpm, 10 rpm, etc., and a pot rotation rate in a range of 4 rpm to 7 rpm, such as 4 rpm, 5 rpm, 6 rpm, 7 rpm, etc.

In the method for preparing the silicon single crystal rod provided in embodiments of the present disclosure, the furnace pressure is less than or equal to 500 Pa, and the pumping rate is greater than or equal to 1,000 m³/h in each operation of the crystal pulling process described above. In this way, by controlling the furnace pressure to be lower and the pumping rate to be higher, the volatilization rate of the oxygen impurities is enhanced and atmosphere circulation inside the single crystal furnace is accelerated, so that pressures of various parts of the single crystal furnace are equalized to avoid imbalance of the pressures of various parts of the single crystal furnace. In addition, the lower furnace pressure and the higher pumping rate are conducive to rapid flow of the inert gas from the guide cylinder to the top of the free liquid surface, and then through the side wall of the crucible to the bottom of the single crystal furnace to discharge. The inert gas flow velocity above the free liquid surface increases, and accordingly, the rate of the oxygen impurities being taken out is faster, so as to reduce the oxygen impurities in the silicon single crystal rod and improve the quality of the silicon single crystal rod.

The single crystal furnace is a device that melts polycrystalline materials such as polycrystalline silicon using a graphite heater in an inert gas (mainly nitrogen and helium) environment, and grows dislocation-free single crystals by the czochralski method. The czochralski method includes melting polysilicon in a crucible made of quartz to obtain a silicon melt, immersing a single-crystal seed into the silicon melt, and continuously pulling the seed to move away from a surface of the silicon melt, thereby growing a silicon single-crystal rod at the interface during the movement. A conventional czochralski silicon single crystal furnace includes a main furnace chamber and a secondary furnace chamber. Crystals are pulled out of the melt and then raised to the interior of the secondary furnace chamber for slow cooling, and the rod is taken out after being cooled.

Oxygen content, as an important testing index of the silicon single crystal rod, has a greater impact on related performance of a single crystal silicon cell. The oxygen in the silicon single crystal rod is mainly from silicon monoxide produced by reaction between the quartz crucible and the molten silicon. The flow rate of argon in the hot field of a conventional monocrystalline furnace is slow, and the volatilized silicon monoxide is unable to be quickly and timely discharged from the quartz crucible, resulting in condensation of SiO into the silicon single crystal rod and increase of the oxygen content of the silicon single crystal rod. The performance of the cell is affected by the high oxygen content in the silicon single crystal rod.

It is seen that the conventional single crystal furnaces have the problem of high oxygen content of the produced silicon single crystal rod.

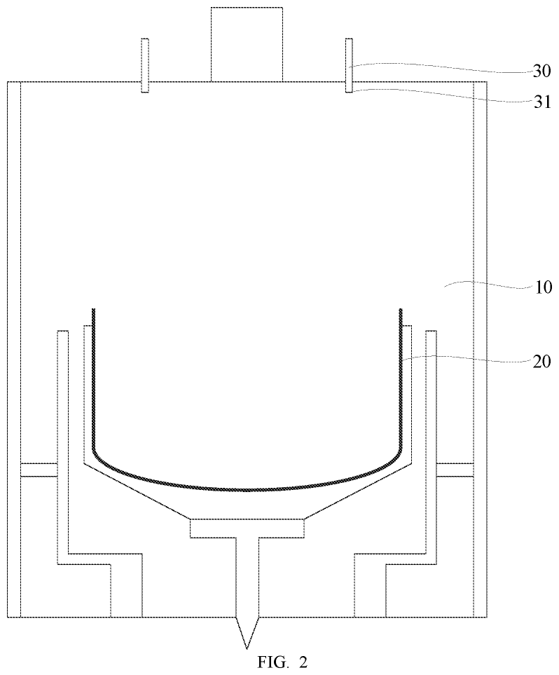

Referring to FIG. 2, in the related technologies, the single crystal furnace includes a furnace chamber 10, a crucible 20, and an inlet pipe 30. The crucible 20 is placed in the furnace chamber 10 and at the bottom of the furnace chamber 10. The inlet pipe 30 has an inlet port 31, and the inlet port 31 is placed at the top of the furnace chamber 10. In the process of producing a silicon single crystal rod using the single crystal silicon furnace, inert gas is passed into the inlet pipe 30, and the inert gas enters into the furnace chamber 10 from the inlet port placed at the top of the furnace chamber 10 and flows downward in the furnace chamber 10 until it flows to the silicon material inside the crucible 20 to take away the oxygen in the silicon material, so that the oxygen content in the silicon material is reduced and the oxygen content in the silicon single crystal rod produced by the single crystal furnace is reduced. However, since the inlet port 31 is placed at the top of the furnace chamber 10, the inert gas needs to be transmitted from the inlet port 31 at the top of the furnace chamber 10 to an upper part of the crucible 20 through a long transmission path, and a large gas loss is generated in the transmission process of the inert gas, so that the flow rate of the gas transmitted to the liquid surface of the crucible 20 is small, and the effect of the inert gas in taking away oxygen from the silicon material is poor. As a result, the oxygen content in the silicon single crystal rod produced by the single crystal furnace is still high, which affects the performance of the cell produced from the silicon single crystal rod as a material.

The related technologies usually use methods of reducing a thickness of the hot field at the bottom or implement the crystal pulling at low furnace pressure to reduce the oxygen content in the silicon single crystal rod produced by the single crystal furnace. However, lowering the thickness of the hot field at the bottom brings about a problem of increased power and increased wire breakage, and lowering the furnace pressure brings about the effects of increased volatility and decreased life of hot field materials. Thus, it is seen that the methods in the related technologies for reducing the oxygen content in the silicon single crystal rod produced by the single crystal furnace have certain defects.

One of the reasons for the above problems in the single crystal furnace is that the gas flow rate of the inert gas for taking away oxygen from the silicon material transmitted above the crucible is low, so that the effect of the inert gas in taking away oxygen from the silicon material is not good, and the oxygen content in the silicon single crystal rod produced by the single crystal furnace is high. If this problem can be changed, the oxygen content in the silicon single crystal rod produced by the single crystal furnace is reduced.

To this end, embodiments of the present disclosure provide a single crystal furnace and a method for preparing a silicon single crystal rod, which are at least conducive to reducing the oxygen content in the silicon single crystal rod.

Some embodiments of the present disclosure provide a single crystal furnace, including: a furnace chamber; a crucible placed inside the furnace chamber and at a bottom of the furnace chamber; a first inlet pipe having a first inlet port, where the first inlet port is placed at a top of the furnace chamber; at least one second inlet pipe, where each of the at least one second inlet pipe has a respective second inlet port, and the respective second inlet port is placed inside the furnace chamber and above the crucible in a melting stage and a crystal pulling stage, and where a distance between the respective second inlet port and the crucible is less than a distance between the first inlet port and the crucible; a flow rate controller for controlling a gas flow rate of the first inlet port and a gas flow rate of the respective second inlet port; and a pressure regulator for regulating a pressure in the furnace chamber to a first preset pressure in the melting stage and to a second preset pressure in the crystal pulling stage, where the second preset pressure is greater than the first preset pressure.

In some embodiments, a length of each of the at least one second inlet pipe extending into the furnace chamber is adjustable to make the distance between the respective second inlet port and the crucible adjustable; and the single crystal furnace further includes a mobile member adjustable inside the furnace chamber, where the mobile member is connected to each of the at least one second inlet pipe, and adjustment of a position of the mobile member inside the furnace chamber drives adjustment of the length of each of the at least one second inlet pipe extending into the furnace chamber.

In some embodiments, the single crystal furnace further includes a water-cooled heat shield structure, where the water-cooled heat shield structure is placed inside the furnace chamber and above the crucible, and the water-cooled heat shield structure includes a water pipe; where each of the at least one second inlet pipe is fixed to the water pipe.

In some embodiments, the distance between the respective second inlet port and the crucible is in a range of 100 mm to 200 mm in the melting stage and the crystal pulling stage.

In some embodiments, the first inlet pipe has a diameter in a range of 20 mm to 50 mm; and/or, each of the at least one second inlet pipe has a diameter in a range of 20 mm to 50 mm.

In some embodiments, the single crystal furnace further includes: an outer draft tube placed inside the furnace chamber and above the crucible, where the outer draft tube has a conical cross-section along an extension direction of the furnace chamber, and a cone angle of the conical cross-section is greater than or equal to 30°.

Some embodiments of the present disclosure further provide a method for preparing a silicon single crystal rod, using the single crystal furnace according to any of the embodiments described above, including: a charging stage, where in the charging stage, a silicon material is placed into the crucible; a melting stage, where in the melting stage, the first inlet port and the respective second inlet port provide an inert gas to the furnace chamber, and the distance between the respective second inlet port and the crucible is less than the distance between the first inlet port and the crucible, and where each of the gas flow rate of the first inlet port and the gas flow rate of the respective second inlet is a first flow rate, and the pressure in the furnace chamber is the first preset pressure; a crystal pulling stage, where in the crystal pulling stage, the first inlet port and the respective second inlet port continuously provide the inert gas into the furnace chamber, and the distance between the respective second inlet port and the crucible is less than the distance between the first inlet port and the crucible, and where each of the gas flow rate of the first inlet port and the gas flow rate of the respective second inlet port is a second flow rate, and the pressure in the furnace chamber is the second preset pressure; and where the first flow rate is greater than the second flow rate, and the first preset pressure is less than the second preset pressure.

In some embodiments, the first flow rate is in a range of 200 L/min to 500 L/min, and the second flow rate is in a range of 150 L/min to 300 L/min.

In some embodiments, the pressure regulator includes a suction pump, and the suction pump has an adjustable opening degree.

In some embodiments, the second preset pressure is in a range of 8 tor to 12 tor, and the suction pump has the opening degree in a range of 70% to 90%; the first preset pressure is in a range of 3 tor to 7 tor, and the suction pump has the opening degree in a range of 95% to 100%.

The technical solution provided in embodiments of the present disclosure has at least the following advantages. The single crystal furnace provided in the embodiments of the present disclosure includes the furnace chamber, the crucible, the first inlet pipe, the at least one second inlet pipe, the flow rate controller, and the pressure regulator. The crucible is placed in the furnace chamber and at the bottom of the furnace chamber, the first inlet port of the first inlet pipe is placed at the top of the furnace chamber, and the respective second inlet port of each of the at least one second inlet pipe is placed inside the furnace chamber and above the crucible. The distance between the respective second inlet port and the crucible is less than the distance between the first inlet port and the crucible. The flow rate controller is configured to control the gas flow rate, and the pressure regulator is configured to regulate the pressure in the furnace chamber, and to make the pressure in the furnace chamber in the melting stage less than the pressure in the furnace chamber in the crystal pulling stage. One of the roles of the gas emitted from the first inlet pipe and each of the at least one second inlet pipe is to take away the oxygen in the silicon material, so that the silicon single crystal rod prepared by the single crystal furnace has a low oxygen content. The inlet pipes transmit the inert gas, the inert gas is transmitted into the furnace chamber through the first inlet port and the respective second inlet port and is then transmitted downward to the silicon material in the crucible, so as to take away the oxygen in the silicon material. In the transmission process, the inert gas produces a certain loss, and the gas flow rate of the inert gas transmitted to the silicon material in the crucible is less than the gas flow rates of the first inlet port and the respective second inlet port. In the embodiments of the present disclosure, the distance between the respective second inlet port and the crucible is relatively close, which reduces the transmission path of the gas flow emitted from the respective second inlet port inside the furnace chamber, so as to reduce the loss of the gas flow rate of the inert gas emitted from the respective second inlet port caused by the transmission of the inert gas inside the furnace chamber. As a result, the flow rate of the gas transmitted to the liquid surface of the crucible is relatively large, so as to make the gas able to take away more oxygen in the silicon material, and effectively reduce the oxygen content in the silicon single crystal rod prepared in the single crystal furnace, thereby improving the performance of the cell produced with the silicon single crystal rod as the raw material. Moreover, the embodiments of the present disclosure use the pressure regulator to make the furnace pressure inside the furnace chamber not too low to increase the volatility and reduce the life of the hot field material, and the embodiments of the present disclosure does not reduce the thickness of the hot field at the bottom, which does not bring about the increase in the power and in the rate of wire breakage.

In order to make the objectives, technical solutions and advantages of the embodiments of the present invention clearer. The embodiments of the present disclosure are described in detail below in connection with the accompanying drawings. However, a person of ordinary skill in the art should understand that, in the various embodiments of the present disclosure, a number of technical details have been proposed in order to enable the reader to better understand the present disclosure. Even without these technical details and various variations and modifications based on the following embodiments, the claimed technical solutions in the present disclosure are also able to be realized.

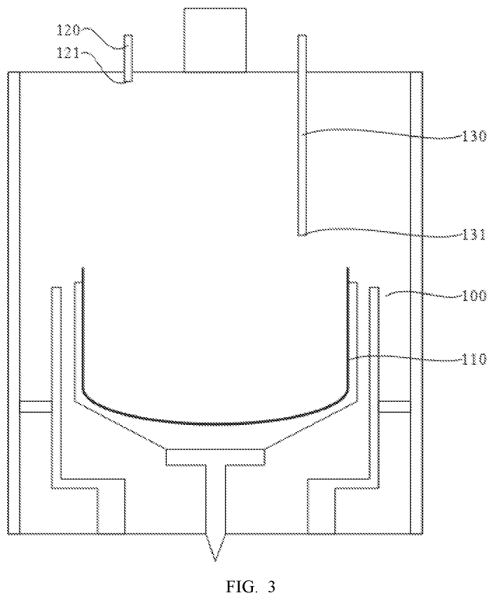

FIG. 3 to FIG. 7 are schematic structural diagrams of a single crystal furnace provided in embodiments of the present disclosure.

Referring to FIG. 3, the single crystal furnace includes a furnace chamber 100, a crucible 110, a first inlet pipe 120 having a first inlet port 121, at least one second inlet pipe 130 each having a respective second inlet port 131, a flow rate controller (not shown), and a pressure regulator (not shown). The crucible 110 is placed inside the furnace chamber 100 and at the bottom of the furnace chamber 100. The first inlet port 121 is placed at the top of the furnace chamber 100, and the respective second inlet port 131 is placed inside the furnace chamber 100 and above the crucible 110 in a melting stage and a crystal pulling stage. A distance between the respective second inlet port 131 and the crucible 110 is less than a distance between the first inlet port 121 and the crucible 110. The flow rate controller is configured to control a gas flow rate of the first inlet port 121 and a gas flow rate of the respective second inlet port 131. The pressure regulator is configured to regulate a pressure in the furnace chamber 100 to a first preset pressure in the melting stage, and regulate the pressure in the furnace chamber 100 to a second preset pressure in the crystal pulling stage. The second preset pressure is greater than the first preset pressure.

Specifically, the furnace chamber 100 is configured to provide a space for the single crystal furnace to prepare the silicon single crystal rod, and the furnace chamber 100 itself has the characteristics of high temperature resistance, good sealing, etc. An inlet pipe is provided at the top of the furnace chamber 100, the inert gas is able to pass into the furnace chamber 100 through the inlet pipe at the top of the furnace chamber 100, and the inert gas is able to take oxygen impurities generated in the preparation out of the furnace chamber 100. Furthermore, the furnace chamber 100 has an excellent heat preservation performance. In the process of preparing the silicon single crystal rod, a high temperature needs to be maintained in the furnace chamber 100. That is, on the one hand, the single crystal furnace needs to be heated, and on the other hand, an excellent heat preservation effect for the temperature in the furnace chamber 100 needs to be provided, so as to satisfy the heat demand in the crystal pulling process of the single crystal furnace and ensure that the crystal pulling process goes smoothly, thereby improving the efficiency of the crystal pulling.

The crucible 110 is a holding space for the silicon material used to prepare the silicon single crystal rod and a container required for melting the silicon material. The crucible 110 is a bowl-shaped structure placed at the bottom of the furnace chamber 100. In the process of preparing the silicon single crystal rod by using the single crystal furnace, the silicon material for preparing the silicon single crystal rod is added into the crucible 110, and then the silicon material in the crucible 110 is melted by increasing the temperature in the furnace chamber 100, and finally the melted silicon material in the crucible 110 is used as a raw material for crystal pulling, so as to be able to prepare the silicon single crystal rod used for preparing cells.

The first inlet pipe 120 is used to pass the inert gas into the furnace chamber 100. The inert gas is passed into the furnace chamber 100 through the first inlet port 121 of the first inlet pipe 120, and flows along an extending direction of the furnace chamber 100 towards the crucible 110. The inert gas passed through the first inlet port 121 is able to take away a certain concentration of oxygen in the silicon material in the crucible 110, thereby reducing the oxygen content in the silicon single crystal rod prepared in the single crystal furnace, and improving the performance of the cells using the single crystal rod as the raw material. Moreover, the inert gas passed into the first inlet pipe 120 also takes away some other impurities in the silicon material, thereby improving the quality of the silicon single crystal rod prepared in the single crystal furnace.

In some embodiments, a diameter of the first inlet port 121 of the first inlet pipe 120 is in a range of 20 mm to 50 mm. For example, the diameter of the first inlet port 121 of the first inlet pipe 120 is 20 mm, 25 mm, 30 mm, 35 mm, 40 mm, 45 mm, 50 mm, and the like. The flow rate controller in the single crystal furnace controls the gas flow rates of the inlet ports of the inlet pipes according to the diameters of the inlet ports. If the diameter of the first inlet port 121 of the first inlet pipe 120 is excessively small, the flow rate controller controls the gas flow rate of the first inlet port 121 of the first inlet pipe to be excessively small as well. Thus, the inert gas passed through the first inlet port 121 is difficult to play a better role in taking away the oxygen in the silicon material, and it is difficult to effectively reduce the oxygen content in the silicon single crystal rod prepared in the single crystal furnace. If the diameter of the first inlet port 121 of the first inlet pipe 120 is excessively large, the flow rate controller controls the gas flow rate of the first inlet port 121 of the first inlet pipe 120 to be excessively large as well. At this time, the increase of the gas flow rate has little effect on the improvement of the effect of the inert gas taking away the oxygen in the silicon material, resulting in certain waste. Therefore, the diameter of the first inlet port 121 of the first inlet pipe 120 needs to be selected in an appropriate range. When the diameter of the first inlet port 121 of the first inlet pipe 120 is in a range of 20 mm to 50 mm, the oxygen content in the silicon single crystal rod prepared in the single crystal furnace is effectively reduced without causing waste.

Each of the at least one second inlet pipe 130 is likewise used to pass the inert gas into the furnace chamber 100. The inert gas is passed into the furnace chamber 100 through the respective second inlet port 131 of each of the at least one second inlet pipe 130, and flows along an extending direction of the furnace chamber 100 towards the crucible 110. The inert gas passed through the respective second inlet port 131 is able to take away a certain concentration of oxygen in the silicon material in the crucible 110, thereby reducing the oxygen content in the silicon single crystal rod prepared in the single crystal furnace, and improving the performance of the cells using the silicon single crystal rod as the raw material. The distance between the respective second inlet port 131 and the crucible 110 is less than the distance between the first inlet port 121 and the crucible 110, which reduces the loss generated when the inert gas emitted from each of the at least one second inlet pipe 130 is transmitted within the furnace chamber 100, and improves the gas flow rate of the inert gas emitted from each of the at least one second inlet pipe 130 at the liquid surface of the crucible 110, thereby further improving the effect of the inert gas to take away the oxygen in the silicon material and more effectively reducing the oxygen content in the silicon single crystal rod prepared in the single crystal furnace. Moreover, the inert gas passed through each of the at least one second inlet pipe 130 is also able to take away some other impurities in the silicon material, thereby improving the quality of the silicon single crystal rod prepared in the single crystal furnace.

In some embodiments, a diameter of the respective second inlet port 131 of each of the at least one second inlet pipe 130 is in a range of 20 mm to 50 mm. For example, the diameter of the respective second inlet port 131 of each of the at least one second inlet pipe 130 is 20 mm, 25 mm, 30 mm, 35 mm, 40 mm, 45 mm, 50 mm, and the like. The flow rate controller in the single crystal furnace controls the gas flow rates of the inlet ports of the inlet pipes according to the diameters of the inlet ports. If the diameter of the respective second inlet port 131 of each of the at least one second inlet pipe 130 is excessively small, the flow rate controller controls the gas flow rate of the respective second inlet port 131 of each of the at least one second inlet pipe 130 to be excessively small as well. Thus, the inert gas passed through the respective second inlet port 131 is difficult to play a better role in taking away the oxygen in the silicon material, and it is difficult to effectively reduce the oxygen content in the silicon single crystal rod prepared in the single crystal furnace. If the diameter of the respective second inlet port 131 of each of the at least one second inlet pipe 130 is excessively large, the flow rate controller controls the gas flow rate of the respective second inlet port 131 of each of the at least one second inlet pipe 130 to be excessively large as well. At this time, the increase of the gas flow rate has little effect on the improvement of the effect of the inert gas taking away the oxygen in the silicon material, resulting in certain waste. Therefore, the diameter of the respective second inlet port 131 of each of the at least one second inlet pipe 130 needs to be selected in an appropriate range. When the diameter of the respective second inlet port 131 of each of the at least one second inlet pipe 130 is in a range of 20 mm to 50 mm, the oxygen content in the silicon single crystal rod prepared in the single crystal furnace is effectively reduced without causing waste.

In some embodiments, the inert gas passed through the first inlet pipe 120 and each of the at least one second inlet pipe 130 includes argon.

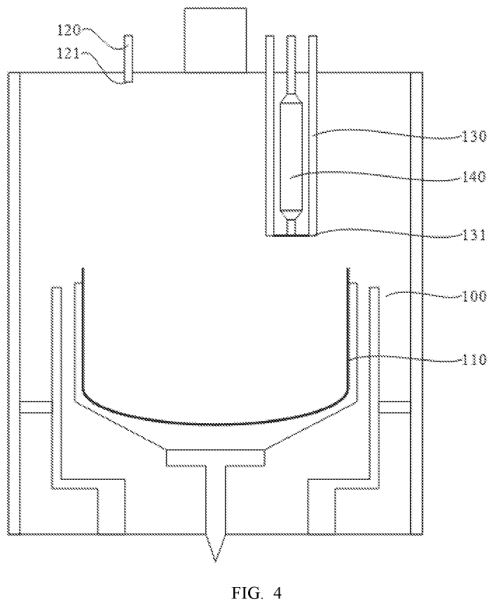

Referring to FIG. 4, in some embodiments, a length of each second inlet pipe 130 extending into the furnace chamber 100 is adjustable to make the distance between the respective second inlet port 131 and the crucible 110 adjustable. The single crystal furnace further includes a movable member 140 adjustable inside the furnace chamber 100. The movable member 140 is connected to each second inlet pipe 130, and adjustment of a position of the mobile member 140 inside the furnace chamber 100 drives adjustment of the length of each second inlet pipe 130 extending into the furnace chamber 100. The mobile member 140 is a tool to drive each second inlet pipe 130 to move. The mobile member 140 moves to drive the second inlet pipe 130 to move inside the furnace chamber 100, so that the respective second inlet port 131 of each second inlet pipe 130 is able to move within the furnace chamber 100 according to the actual need so as to adjust the distance between the respective second inlet port 131 and the crucible 110. Moreover, the mobile member 140 driving each second inlet pipe 130 to move inside the furnace chamber 100 makes each second inlet pipe 130 in different positions in different operations of the preparation of the silicon single crystal rod, which is convenient for perfecting the preparation process and improving the preparation efficiency.

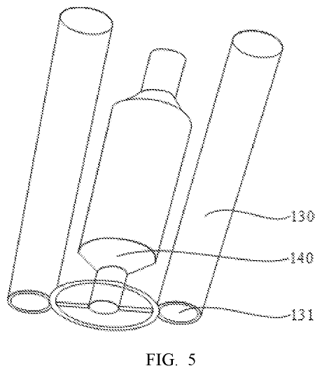

FIG. 5 shows a schematic structural diagram of a weight connected to the second inlet pipe provided in embodiments of the present disclosure. Referring to FIG. 5, in some embodiments, the mobile member 140 includes a weight. The weight is a fixture that is able to be connected to each second inlet pipe 130 to drive each second inlet pipe 130 to move within the furnace chamber 100, such that the distance between the respective second inlet port 131 and the crucible 110 is adjustable. In this way, the distance between the respective second inlet port 131 and the crucible 110 is adjusted according to actual needs.

Continuing to refer to FIG. 5, in some embodiments, the number of the at least one second inlet pipes 130 is greater than or equal to two. The plurality of second inlet pipes 130 increase the gas flow rate of the inert gas in the furnace chamber 100 that is passed to the silicon material at the crucible 110, which increases the oxygen in the silicon material that is taken away by the inert gas, and thus further reduces the oxygen content in the silicon single crystal rod prepared in the single crystal furnace.

In some embodiments, one second inlet pipe 130 is provided, and the mobile member 140 is connected to one second inlet pipe 130 (not shown) to drive the second inlet pipe 130 to move within the furnace chamber 100.

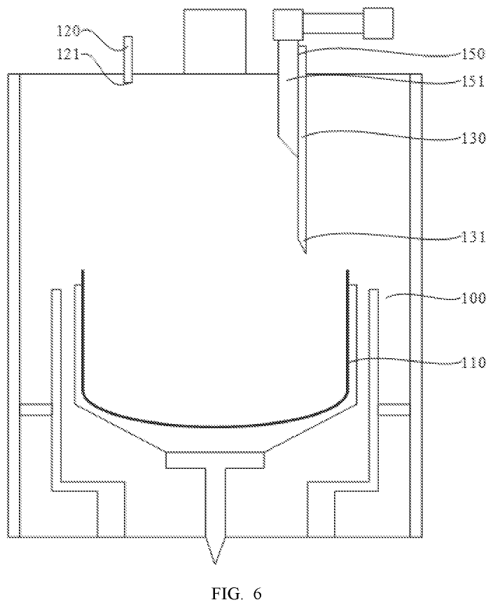

Referring to FIG. 6, in some embodiments, the single crystal furnace further includes a water-cooled heat shield structure 150, the water-cooled heat shield structure 150 is placed inside the furnace chamber 100 and above the crucible 110, and the water-cooled heat shield structure 150 includes a water pipe 151. The second inlet pipe 130 is fixed to the water pipe 151. In the process of silicon single crystal rod growth, a latent heat loss rate of crystallization is significantly reduced as the crystal continuously grows, resulting in slip and climbing movement of crystal lattice arrangement during crystal growth and proliferation of dislocations. The proliferation of dislocations leads to the change of atomic spacing, and increase of interatomic force in some crystal lattices leads to the fracture of interatomic bonds, which is reflected as bract fracture and disappearance of crystal lines on a macro level. The latent heat of crystallization during crystal growth is taken away by passing cold water through the water pipe 151 of the water-cooled heat shield structure 150. The water-cooled heat shield structure 150 is placed above the crucible 110, and the second inlet pipe 130 is connected to the water-cooled heat shield structure 150 to realize that the distance between the second inlet port 131 and the crucible 110 is less than the distance between the first inlet port 121 and the crucible 110. As a result, a transmission path of the gas flow emitted from the second inlet pipe 130 inside the furnace chamber 100 is reduced, and the loss of the gas flow rate caused by the transmission of the gas flow emitted from the second inlet port 131 inside the furnace chamber 100, so that the gas flow rate at the liquid surface in the crucible 110 is larger, which is able to take away more oxygen in the silicon material, thereby reducing the oxygen content in the silicon single crystal rod prepared in the single crystal furnace. Moreover, the second inlet pipe 130 is connected to the water-cooled heat shield structure 150 to improve integration of internal components of the single crystal furnace and reduce complexity of the single crystal furnace, and the second inlet pipe 130 and the water-cooled heat shield structure 150 are placed in the furnace chamber 100 together all the time without moving, so that the complexity of the preparation process is reduced, and the preparation efficiency is improved.

In some embodiments, the distance between the respective second inlet port 131 and the crucible 100 in the melting stage and the crystal pulling stage is in a range of 100 mm to 200 mm. For example, the distance between the respective second inlet port 131 and the crucible 110 in the melting stage and the crystal pulling stage is 100 mm, 120 mm, 140 mm, 150 mm, 160 mm, 180 mm, 200 mm, etc. If the distance between the second inlet port 131 and the crucible 100 is relatively small in the melting stage and the crystal pulling stage, the distance between the second inlet port 131 and the liquid silicon material melted in the crucible 110 is relatively small, and the inert gas emitted from the second inlet port 131 may cause the liquid silicon material in the crucible 110 to splash. If the distance between the second inlet port 131 and the crucible 110 is relatively large in the melting stage and the crystal pulling stage, the inert gas emitted from the second inlet port 131 still needs to transmit a distance and then to the liquid surface, which causes a certain amount of gas flow rate loss in the process of transmission, so that the effect of the inert gas emitted from the second inlet port 131 in taking away the oxygen in the silicon material is not good, and it is difficult to effectively reduce the oxygen content in the silicon single crystal rod prepared in the single crystal furnace. Therefore, in the melting stage and the crystal pulling stage, the distance between the second inlet port 131 and the crucible 110 needs to be selected in an appropriate range. When the distance between the second inlet port 131 and the crucible 110 is in a range of 100 mm to 200 mm, the inert gas in the second inlet port 131 effectively takes away the oxygen in the silicon material without causing splashing.

It should be understood that if the length of each of the at least one second inlet pipe 130 extending into the furnace chamber 100 is adjustable, the second inlet pipe 130 is able to be placed at the top of the furnace chamber 100 before the melting operation. Before the melting operation, the mobile member 140 drives each of the at least one second inlet pipe 130 to move above the crucible 110, so that the distance between the respective second inlet port 131 and the crucible 110 is in a range of 100 mm to 200 mm. After the crystal pulling operation, the mobile member 140 drives each of the at least one second inlet pipe 130 upward to the top of the furnace chamber 100. If the length of each of the at least one second inlet pipe 130 extending into the furnace chamber 100 is not adjustable, each of the at least one second inlet pipe 130 is connected to the water-cooled heat shield structure 150, and the distance between the respective second inlet port 131 and the crucible 110 is able to be in a range of 100 mm to 200 mm at all times.

In some embodiments, the pressure regulator includes a suction pump (not shown) and the opening degree of the suction pump is adjustable. The suction pump is placed at the bottom of the furnace chamber 100 to draw the gas within the furnace chamber 100 downwards. It should be understood that the pressure in the furnace chamber 100 is determined by the gas flow rate of the gas passed through the first inlet pipe 120 and each of the at least one second inlet pipe 130 together with the opening degree of the suction pump. The pressure in the furnace chamber 100 is adjusted by adjusting the opening degree of the suction pump. The opening degree can be understood as an opening frequency of the suction pump, the larger the opening degree of the suction pump, the larger the opening frequency of the suction pump, the more energy the suction pump needs to spend to extract the gas inside the furnace chamber 100, and the smaller the pressure inside the furnace chamber 100.

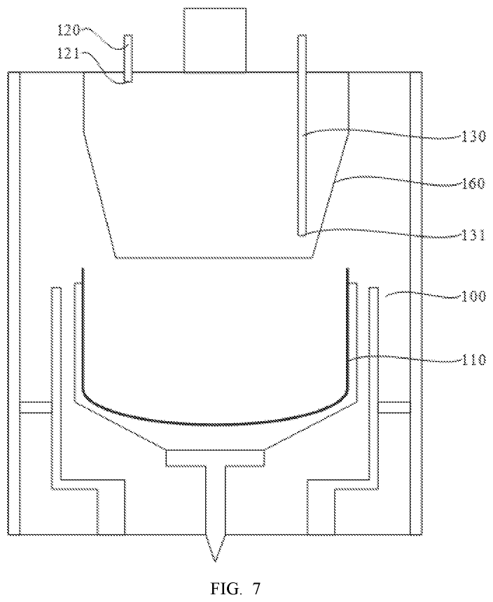

Referring to FIG. 7, in some embodiments, the single crystal furnace further includes an outer draft tube 160, the outer draft tube 160 is placed inside the furnace chamber 100 and above the crucible 110, and the outer draft tube 160 has a conical cross-section along an extension direction of the furnace chamber 100, and a cone angle of the conical cross-section is greater than or equal to 30°. For example, the cone angle of the conical cross-section is 30°, 35°, 40°, 45°, 50°, 60°, and the like. As shown in FIG. 7, the conical cross-section of the outer draft tube 160 is in an open-cone shape, and the cone angle of the conical cross-section refers to an inclined angle generated by extension of two bevel edges of the open-cone shaped cross-section. The outer draft tube 160 is able to direct and regulate the gas in the furnace chamber 100 and provide heat insulation. If the cone angle of the conical cross-section is relatively small, the gas flow is less smooth, which affects the smooth flow of the gas in the furnace chamber 100 and taking away the oxygen in the silicon material. Therefore, the cone angle of the conical cross-section of the outer draft tube along the extension direction of the furnace chamber 100 needs to be selected in an appropriate range. When the cone angle of the conical cross-section is greater than or equal to 30°, the gas flow is smooth, which is conducive for the gas to take away the oxygen in the silicon material.

The embodiments of the present disclosure provide the single crystal furnace including the furnace chamber, the crucible, the first inlet pipe having the first inlet port, at least one second inlet pipe each having the respective second inlet port, the flow rate controller, and the pressure regulator. The crucible is placed inside the furnace chamber and at the bottom of the furnace chamber. The first inlet port is placed at the top of the furnace chamber, and the respective second inlet port is placed inside the furnace chamber and above the crucible in the melting stage and the crystal pulling stage. The distance between the respective second inlet port and the crucible is less than the distance between the first inlet port and the crucible. The flow rate controller is configured to control the gas flow rate of the first inlet port and the gas flow rate of the respective second inlet port. The pressure regulator is configured to regulate the pressure in the furnace chamber to the first preset pressure in the melting stage, and regulate the pressure in the furnace chamber to the second preset pressure in the crystal pulling stage. The second preset pressure is greater than the first preset pressure. In this way, the loss of the gas flow rate caused by the transmission of the gas flow emitted from the second inlet port in the furnace chamber is reduced, so that the gas flow transmitted to the liquid surface in the crucible is larger, and the gas is able to take away more oxygen in the silicon material, thereby effectively reducing the oxygen content in the silicon single crystal rod prepared in the single crystal furnace, and improving the performance of the cells prepared by using the silicon single crystal rod as the raw material.

Accordingly, some embodiments of the present disclosure further provide a method for preparing a silicon single crystal rod, using the above-described single crystal furnace for crystal pulling. The method for preparing the silicon single crystal rod provided in the embodiments of the present disclosure is described in detail in the following in combination with the accompanying drawings, and the same or corresponding parts as previous embodiments can be referred to the corresponding description of the previous embodiments, which are not described in detail in the following.

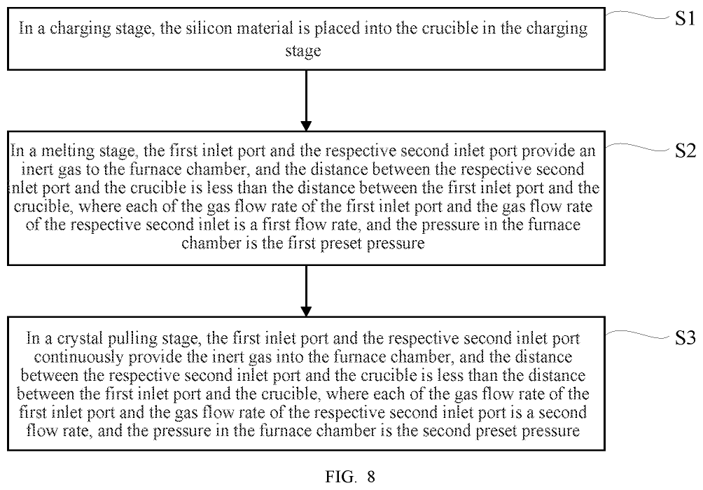

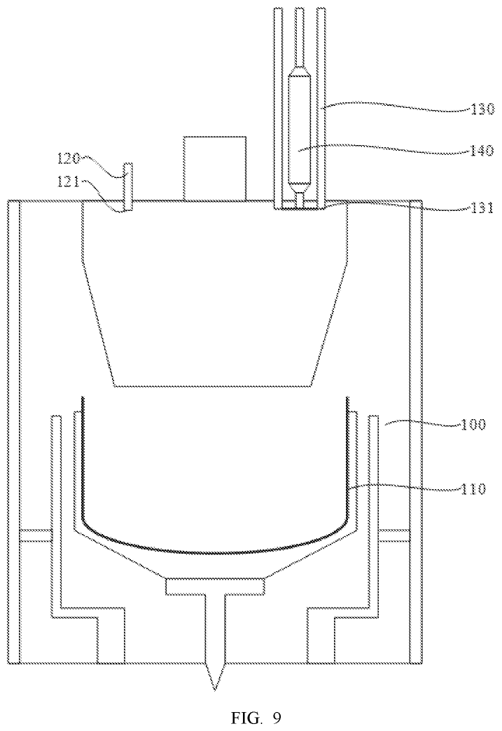

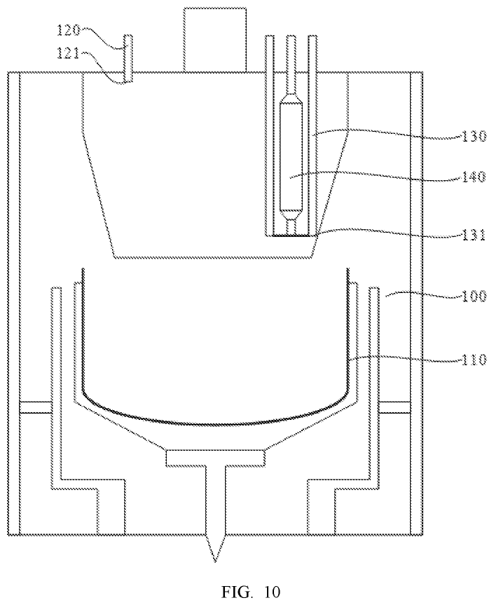

FIG. 8 is a flowchart of each operation in the method for preparing the silicon single crystal rod provided in the embodiments of the present disclosure. FIG. 9 to FIG. 10 are schematic structural diagrams corresponding to some operations of the method for preparing the silicon single crystal rod provided in the embodiments of the present disclosure.

As shown in FIG. 8 and FIG. 9, S1 refers to a charging stage, the silicon material is placed into the crucible 110 in the charging stage.

The silicon material placed in the crucible 110 includes a solid silicon material. In some embodiments, the silicon material includes polysilicon, dopants, and the like.

When placing the silicon material, the respective second inlet port 131 of each second inlet pipe 130 is able to be placed at the top of the furnace chamber 100. Alternatively, the respective second inlet port 131 of each second inlet pipe 130 is placed at the top of the crucible 110.

In some embodiments, the length of each of the at least one second inlet pipe 130 extending into the furnace chamber 100 is adjustable so that the distance between the second inlet port 131 and the crucible 110 is adjustable, and the mobile member 140 is connected to each of the at least one second inlet pipe 130, and adjustment of the position of the mobile member 140 inside the furnace chamber 100 drives adjustment of the length of each of the at least one second inlet pipe 130 extending into the furnace chamber 100. FIG. 9 shows a schematic structural diagram of the second inlet pipes with the mobile member placed at the top of the furnace chamber before the melting stage.

As shown in FIG. 8 and FIG. 10, S2 refers to the melting stage, the first inlet port 121 and the respective second inlet port 131 provide the inert gas to the furnace chamber 100, and the distance between the respective second inlet port 131 and the crucible 110 is less than the distance between the first inlet port 121 and the crucible 110. The gas flow rate of the first inlet port 121 as well as the gas flow rate of the respective second inlet port 131 is the first flow rate, and the pressure in the furnace chamber 100 is the first preset pressure.

In the melting stage, the solid silicon material in the crucible 110 is melted into a liquid. The furnace chamber 100 is first evacuated to a vacuum state, and a heating device is turned on to increase the temperature to melt the silicon material after passing a leakage test.

Referring to FIG. 10, in some embodiments, the length of each second inlet pipe 130 extending into the furnace chamber 100 is adjustable to make the distance between the respective second intake port 131 and the crucible 110 adjustable, and the mobile member 140 is connected to each second inlet pipe 130. Before the melting stage, the mobile member 140 drives each second inlet pipe 130 downwardly until the respective second inlet port 131 of each second inlet pipe 130 is placed above the crucible 110. During the melting stage, each second inlet pipe 130 and the first inlet pipe 120 continuously pass the inert gas into the furnace chamber 100, and the proximity of each second inlet pipe 130 to the crucible 110 enables the inert gas emitted from each second inlet pipe 130 to take away more oxygen from the silicon material, thereby enabling the silicon single crystal rod prepared in the single crystal furnace to have a low oxygen content.

Referring to FIG. 8 and FIG. 10, S3 refers to a crystal pulling stage, the first inlet port 121 and the respective second inlet port 131 continuously provide the inert gas to the furnace chamber 100 in the crystal pulling stage, and the distance between the respective second inlet port 131 and the crucible 110 is less than the distance between the first inlet port 121 and the crucible 110. The gas flow rate of the first inlet port 121 as well as the gas flow rate of the respective second inlet port 131 is the second flow rate, and the pressure in the furnace chamber 100 is the second preset pressure. The crystal pulling stage is a stage of preparing the silicon single crystal rod, which is specifically divided into a plurality of operations such as seeding, shoulder releasing, shoulder rotating, diameter equalizing, and closing as described above.

In some embodiments, in the melting stage and the crystal pulling stage, the distance between the respective second inlet port 131 and the crucible 100 is in a range of 100 mm to 200 mm. For example, the distance between the respective second inlet port 131 and the crucible 110 in the melting stage and the crystal pulling stage is 100 mm, 120 mm, 140 mm, 150 mm, 160 mm, 180 mm, 200 mm, etc. If the distance between the second inlet port 131 and the crucible 100 is relatively small in the melting stage and the crystal pulling stage, the distance between the second inlet port 131 and the liquid silicon material melted in the crucible 110 is relatively small, and the inert gas emitted from the second inlet port 131 may cause the liquid silicon material in the crucible 110 to splash. If the distance between the second inlet port 131 and the crucible 110 is relatively large in the melting stage and the crystal pulling stage, the inert gas emitted from the second inlet port 131 still needs to transmit a distance and then to the liquid surface, which causes a certain amount of gas flow rate loss in the process of transmission, so that the effect of the inert gas emitted from the second inlet port 131 in taking away the oxygen in the silicon material is not good, and it is difficult to effectively reduce the oxygen content in the silicon single crystal rod prepared in the single crystal furnace. Therefore, in the melting stage and the crystal pulling stage, the distance between the second inlet port 131 and the crucible 110 needs to be selected in an appropriate range. When the distance between the second inlet port 131 and the crucible 110 is in a range of 100 mm to 200 mm, the inert gas in the second inlet port 131 effectively takes away the oxygen in the silicon material without causing splashing.

In addition, the first flow rate in the melting stage is greater than the second flow rate in the crystal pulling stage, and the first preset pressure in the furnace chamber 100 in the melting stage is less than the second preset pressure in the furnace chamber 100 in the crystal pulling stage. This is due to the fact that the inert gas is able to take away more oxygen from the silicon material in the melting stage relative to the crystal pulling stage, so having a higher gas flow rate in the melting stage is conducive to improving the effect of the inert gas to take away the oxygen from the silicon material, thereby further reducing the oxygen content in the silicon single crystal rod prepared in the single crystal furnace.

In some embodiments, the first flow rate in the melting stage is in a range of 200 L/min to 500 L/min, and the second flow rate in the crystal pulling stage is in a range of 150 L/min to 300 L/min. For example, the first flow rate is 200 L/min, 300 L/min, 400 L/min, 500 L/min, etc. The second flow rate is 150 L/min, 200 L/min, 250 L/min, 300 L/min, etc. If the first flow rate or the second flow rate is too large, it may cause certain waste. If the first flow rate or the second flow rate is too small, the inert gas passed through the first inlet port 121 is difficult to play a better effect of taking away the oxygen in the silicon material, and it is difficult to effectively reduce the oxygen content in the silicon single crystal rod prepared in the single crystal furnace. Therefore, the first flow rate and the second flow rate need to be selected in an appropriate range. When the first flow rate is in the range of 200 L/min to 500 L/min and the second flow rate is in the range of 150 L/min to 300 L/min, the oxygen content in the silicon single crystal rod prepared in the single crystal furnace is effectively reduced without causing waste.

In some embodiments, the pressure regulator includes a suction pump (not shown) and the opening degree of the suction pump is adjustable. The suction pump is placed at the bottom of the furnace chamber 100 to draw the gas within the furnace chamber 100 downwards. It should be understood that the pressure in the furnace chamber 100 is determined by the gas flow rate of the gas passed through the first inlet pipe 120 and each of the at least one second inlet pipe 130 together with the opening degree of the suction pump. The pressure in the furnace chamber 100 is adjusted by adjusting the opening degree of the suction pump. The opening degree can be understood as an opening frequency of the suction pump, the larger the opening degree of the suction pump, the larger the opening frequency of the suction pump, the more energy the suction pump needs to spend to extract the gas inside the furnace chamber 100, and the smaller the pressure inside the furnace chamber 100.

In some embodiments, the second preset pressure is in a range of 8 tor to 12 tor, and the opening degree of the suction pump is in a range of 70%-90%. The first preset pressure is in a range of 3 tor to 7 tor and the opening degree of the suction pump is in a range of 95% to 100%. For example, the second preset pressure is 8 tor, 9 tor, 10 tor, 11 tor, 12 tor, etc., and the opening degree of the suction pump is 70%, 80%, 90%, etc. The first preset pressure is 3 tor, 4 tor, 5 tor, 6 tor, 7 tor, etc., and the opening degree of the suction pump is 95%, 96%, 97%, 98%, 99%, 100%, etc. According to the above, the opening degree of the suction pump is able to regulate the pressure in the furnace chamber. If the second preset pressure or the first preset pressure is too small, the volatility of the hot field material is enhanced and the life of the hot field material is reduced. If the second preset pressure or the first preset pressure is too large, the safety of the process production is reduced, which is risky. Therefore, the second preset pressure and the first preset pressure need to be selected in an appropriate range. When the second preset pressure is in a range of 8 tor to 12 tor, the opening degree of the suction pump is in a range of 70% to 90%, the first preset pressure is in a range of 3 tor to 7 tor, and the opening degree of the suction pump is in a range of 95% to 100%, not only the volatility of the hot field material is not strengthened and the life of the hot field material is not lowered, but also the safety of the preparation is ensured.

Embodiments of the present disclosure provide a method for preparing a silicon single crystal rod, using the above-described single crystal furnace for crystal pulling. Firstly in the charging stage, the silicon material is placed into the crucible. Then in the melting stage, the first inlet port and the respective second inlet port provide the inert gas to the furnace chamber, and the distance between the respective second inlet port and the crucible is less than the distance between the first inlet port and the crucible, where each of the gas flow rate of the first inlet port and the gas flow rate of the respective second inlet is the first flow rate, and the pressure in the furnace chamber is the first preset pressure. Next to the crystal pulling stage, the first inlet port and the respective second inlet port continuously provide the inert gas into the furnace chamber in the crystal pulling stage, and the distance between the respective second inlet port and the crucible is less than the distance between the first inlet port and the crucible, where each of the gas flow rate of the first inlet port and the gas flow rate of the respective second inlet port is the second flow rate, and the pressure in the furnace chamber is the second preset pressure. The first flow rate is greater than the second flow rate, and the first preset pressure is less than the second preset pressure. In the melting stage and the crystal pulling stage, the distance between the second inlet port and the crucible is closer, which reduces the loss of the gas flow rate caused by the transmission of the gas flow emitted from the second inlet port in the furnace chamber, so as to make the gas flow transmitted to the liquid surface of the crucible larger, so that the gas flow transmitted to the liquid surface in the crucible is larger, and the gas is able to take away more oxygen in the silicon material, thereby effectively reducing the oxygen content in the silicon single crystal rod prepared in the single crystal furnace, and improving the performance of the cells prepared by using the silicon single crystal rod as the raw material.

It should be understood by those of ordinary skill in the art that the above embodiments are specific embodiments for realizing the present disclosure. However, in actual application, various changes are able to be made to these embodiments in form and details without departing from the scope of the present disclosure.

What is claimed is:

1. A method for preparing a silicon single crystal rod, comprising:
a crystal pulling process including a melt contacting operation to preheat a seed crystal and drop the seed crystal to a surface of a melt to make full contact with the melt, a seeding operation to insert the seed crystal into the melt and pull a crystal from the melt, a shoulder releasing operation to increase a diameter of the crystal pulled from the melt to a target diameter, a shoulder rotating operation to control growth of the crystal at the target diameter, a diameter equalizing operation to obtain dislocation-free growth of the crystal, and a closing operation to prevent dislocation reverse-extension into the crystal, wherein each operation of the crystal pulling process is conducted in a single crystal furnace having a furnace pressure less than or equal to 500 Pa and a pumping rate greater than or equal to 1000 m³/h.

2. The method according to claim 1, wherein a furnace pressure of each operation gradually decreases as the crystal pulling process advances.

3. The method according to claim 2, wherein a furnace pressure of the melt contacting operation is in a range of 450 Pa to 500 Pa, a furnace pressure of the seeding operation is in a range of 400 Pa to 450 Pa, a furnace pressure of the shoulder releasing operation is in a range of 400 Pa to 450 Pa, a furnace pressure of the shoulder rotating operation is in a range of 300 Pa to 400 Pa, a furnace pressure of the diameter equalizing operation is in a range of 300 Pa to 400 Pa, and a furnace pressure of the closing operation is in a range of 300 Pa to 400 Pa.

4. The method according to claim 1, wherein an inert gas flow rate of each operation gradually decreases as the crystal pulling process advances.

5. The method according to claim 4, wherein an inert gas flow rate of the melt contacting operation is in a range of 120 slpm to 150 slpm, an inert gas flow rate of the seeding operation is in a range of 100 slpm to 120 slpm, an inert gas flow of the shoulder releasing operation is in a range of 100 slpm to 120 slpm, an inert gas flow of the shoulder rotating operation is in a range of 100 slpm to 120 slpm, an inert gas flow rate of the diameter equalizing operation is in a range of 100 slpm to 120 slpm, and an inert gas flow rate of the closing operation is in a range of 100 slpm to 120 slpm.

6. The method according to claim 1, wherein a crystal rotation rate and a pot rotation rate of each operation gradually increase as the crystal pulling process advances.

7. The method according to claim 6, wherein a crystal rotation rate of the melt contacting operation is in a range of 6 rpm to 10 rpm, and a pot rotation rate of the melt contacting operation is in a range of 2 rpm to 6 rpm; a crystal rotation rate of the seeding operation is in a range of 6 rpm to 10 rpm, and a pot rotation rate of the seeding operation is in a range of 2 rpm to 6 rpm; a crystal rotation rate of the shoulder releasing operation is in a range of 6 rpm to 10 rpm, and a pot rotation rate of the shoulder releasing operation is in a range of 2 rpm to 6 rpm; a crystal rotation rate of the shoulder rotating operation is in a range of 8 rpm to 10 rpm, and a pot rotation rate of the shoulder rotating operation is in a range of 4 rpm to 7 rpm; a crystal rotation rate of the diameter equalizing operation is in a range of 8 rpm to 10 rpm, and a pot rotation rate of the diameter equalizing operation is in a range of 4 rpm to 7 rpm; and a crystal rotation rate of the closing operation is in a range of 8 rpm to 10 rpm, and a pot rotation rate of the closing operation is in a range of 4 rpm to 7 rpm.

8. The method according to claim 1, wherein a pumping rate of the melt contacting operation is greater than pumping rates of other operations in the crystal pulling process.

9. The method according to claim 8, wherein a pumping rate of each operation following the melt contacting operation gradually increases as the crystal pulling process advances.

10. The method according to claim 9, wherein the pumping rate of the melt contacting operation is in a range of 2100 m³/h to 2300 m³/h, a pumping rate of the seeding operation is in a range of 1600 m³/h to 1800 m³/h, a pumping rate of the shoulder releasing operation is in a range of 1600 m³/h to 1800 m³/h, a pumping rate of the shoulder rotating operation is in a range of 1600 m³/h to 1800 m³/h, a pumping rate of the diameter equalizing operation is in a range of 1800 m³/h to 2100 m³/h, and a pumping rate of the closing operation is in a range of 1800 m³/h to 2100 m³/h.

11. The method according to claim 1, wherein the shoulder releasing operation includes a flat shoulder releasing process.

12. A single crystal furnace, in which each operation in the method according to claim 1 is conducted, comprising:
a furnace chamber;
a crucible placed inside the furnace chamber and at a bottom of the furnace chamber;
a first inlet pipe having a first inlet port, wherein the first inlet port is placed at a top of the furnace chamber;
at least one second inlet pipe, wherein each of the at least one second inlet pipe has a respective second inlet port, and the respective second inlet port is placed inside the furnace chamber and above the crucible in a melting stage and a crystal pulling stage, and wherein a distance between the respective second inlet port and the crucible is less than a distance between the first inlet port and the crucible;
a flow rate controller for controlling a gas flow rate of the first inlet port and a gas flow rate of the respective second inlet port; and
a pressure regulator for regulating a pressure in the furnace chamber to a first preset pressure in the melting stage and to a second preset pressure in the crystal pulling stage, wherein the second preset pressure is greater than the first preset pressure.

13. The single crystal furnace according to claim 12, wherein a length of each of the at least one second inlet pipe extending into the furnace chamber is adjustable to make the distance between the respective second inlet port and the crucible adjustable; and
the single crystal furnace further comprising:
a mobile member adjustable inside the furnace chamber, wherein the mobile member is connected to each of the at least one second inlet pipe, and adjustment of a position of the mobile member inside the furnace chamber drives adjustment of the length of each of the at least one second inlet pipe extending into the furnace chamber.

14. The single crystal furnace according to claim 12, further comprising: a water-cooled heat shield structure, wherein the water-cooled heat shield structure is placed inside the furnace chamber and above the crucible, and the water-cooled heat shield structure includes a water pipe; wherein each of the at least one second inlet pipe is fixed to the water pipe.

15. The single crystal furnace according to claim 12, wherein the distance between the respective second inlet port and the crucible is in a range of 100 mm to 200 mm in the melting stage and the crystal pulling stage.

16. The single crystal furnace according to claim 12, wherein the first inlet pipe has a diameter in a range of 20 mm to 50 mm.

17. The single crystal furnace according to claim 12, wherein each of the at least one second inlet pipe has a diameter in a range of 20 mm to 50 mm.

18. The single crystal furnace according to claim 12, further comprising: an outer draft tube placed inside the furnace chamber and above the crucible, wherein the outer draft tube has a conical cross-section along an extension direction of the furnace chamber, and a cone angle of the conical cross-section is greater than or equal to 30°.

19. The single crystal furnace according to claim 13, wherein the mobile member includes a weight configured to be connected to each of the at least one second inlet pipe to drive each of the at least one second inlet pipe to move within the furnace chamber.

20. The single crystal furnace according to claim 12, wherein the pressure regulator includes a suction pump, and an opening degree of the suction pump is adjustable.
